(19) United States
(12) Patent Application Publication
(10) Pub. No.: US 2005/0286415 A1
(43) Pub. Date: Dec. 29, 2005

(54) System and method for lightweight deadlock detection

(75) Inventor: Qun Guo, Redmond, WA (US)

Correspondence Address: WOODCOCK WASHBURN LLP (MICROSOFT CORPORATION), ONE LIBERTY PLACE - 46TH FLOOR, PHILADELPHIA, PA, 19103, US

(73) Assignee: Microsoft Corporation, Redmond, WA (US)

(21) Appl. No.: 10/878,163

(22) Filed: Jun. 28, 2004

(51) Int. Cl. G01R 31/08; G08C 15/00; H04L 12/26; G06F 11/00; H04J 3/14; H04J 1/16; H04L 1/00; H04L 12/28; H04B 1/44

(52) U.S. Cl. 370/225; 370/431

(57) ABSTRACT

The present invention is directed to systems and methods for lightweight deadlock detection among a number of parallel transacted connections. Rather than employing an additional separate monitoring connection, the present invention enables a transacted connection to query the subscriber and determine a connection status for other connections within the same transaction. The transacted connection queries the subscriber when the transacted connection is idle, thereby minimizing overhead and yielding better throughput. The elimination of the separate monitoring connection conserves network bandwidth and system processing capability.

### FIELD OF THE INVENTION

The present invention relates to the field of transactional data replication, and, more specifically, to detecting a deadlock between an application and connections within a subscriber.

### BACKGROUND OF THE INVENTION

Parallel transactions improve transactional throughput by replicating changes (e.g. insertions, deletions, modifications) to a subscriber through a number of different connection streams. Thus, to protect against committing some connections while rolling back others, a connection based synchronization model is employed. When a connection is ready to be committed, the connection sets its synchronization state to ready and remains idle. The ready connection waits on the synchronization states from all other connections from the same application to set their synchronization state to ready. Since the connection has not been committed, it continues to hold a lock it acquired on a subscriber resource (e.g. table, row, index, etc). Meanwhile, if another connection (either from the same application or from a different application) attempts to change the locked resource, the other connection will be blocked until this connection commits and the lock is removed.

One problem that is associated with parallel transactions is undetected connection deadlock. Such deadlock occurs when a first connection is blocked by a second connection from within the same application. In this scenario, the first connection cannot be committed because the second connection is part of the same application and is not yet ready to be committed. However, the second connection cannot reach the ready to commit state because it is blocked by the first connection. Moreover, because the second connection is in the process of accessing a resource, it is unable communicate a notification of its blocked status.

A conventional solution to the problem of parallel transaction deadlock involves a distributed transaction coordinator (DTC). The DTC is a separate module that monitors each of the transacted connections. When the DTC detects that a connection is blocked, the DTC determines whether the blocking connection is within the same application as the blocked connection. If the blocking connection is part of another application, then the blocked connection simply need wait until the other connection commits or fails and the lock is removed. However, if the blocking connection is part of the same application, then a deadlock has occurred and the blocked connection will fail. Typically, when a deadlock is detected, the transaction is aborted and any internal conflicts are resolved. The transaction may then be retried in a consistent state.

An exemplary prior art deadlock detection system is shown in FIG. 1. Application 101 manages transacted connections 102, including Connections A and B. Transacted connections 102 replicate data from application 101 to data table 112 within subscriber 111. DTC 103 is a separate connection that monitors transacted connections 102. As shown by the thick grid surrounding lines, Connection B has acquired a lock on row 2 of table 112. Thus, Connection B is ready to commit and is an idle state, as represented by the dashed line. Connection A, meanwhile, is also attempting to acquire a lock on row 2. However, because Connection B has already acquired a lock on row 2, Connection A is blocked from accessing row 2, as represented by the encircled “X”. The transaction cannot be committed until both Connections A and B are ready to commit. However, Connection B cannot release its lock on row 2 until the transaction has committed. Thus, a deadlock has occurred. DTC 103 detects the deadlock and notifies application 101, which takes appropriate action to resolve the deadlock.

The conventional system set forth above involves several drawbacks. For example, the DTC 103 requires an additional separate module from the application 101, thereby occupying valuable network bandwidth and requiring additional system processing capability. In addition, commercial DTC products are generally limited to strict two phase commit (2PC) protocol, which is not a universal protocol. Thus, there is a need in the art for systems and methods for lightweight deadlock detection that conserve both network bandwidth and system processing capability, thereby improving performance of parallel transactions. The present invention satisfies these and other needs.

### SUMMARY OF THE INVENTION

The present invention is directed to systems and methods for lightweight deadlock detection among a number of distributed transacted connections. Rather than employing an additional separate monitoring connection, the present invention enables an existing idle connection to query the subscriber and determine a connection status for other connections within the same application. The elimination of the separate monitoring connection conserves network bandwidth and system processing capability.

According to an aspect of the invention, when a first transacted connection becomes ready to commit, a counting of a pre-determined time period is initiated. If, prior to expiration of the pre-determined time period, all of the other connections within the application also become ready to commit, then the transaction is committed. If, however, the time period expires before the transaction commits, then the subscriber is queried to determine whether a deadlock has occurred. The subscriber may be queried with any of the idle transacted connections that are ready to commit.

According to another aspect of the invention, the subscriber is queried to obtain a connection status for each of the transacted connections. The connection status includes an indication of whether a corresponding connection is blocked and, if so, the identity of the blocking connection. If a transacted connection is blocked by another of the transacted connections, then a deadlock is detected. If a deadlock is not detected, then the querying connection is returned to its idle state, and the counting of the pre-determined time period is re-initiated. The process may be repeated recursively until either the transaction commits or a deadlock is detected.

According to another aspect of the invention, upon initiation of the transaction, a list of connection identifiers for each of the transacted connections may be retrieved from the subscriber. The retrieved connection identifiers may be used to query the subscriber to obtain the connection status for the transacted connections and to determine whether any of the transacted connections are blocked by other transacted connections.

Additional features and advantages of the invention will be made apparent from the following detailed description of illustrative embodiments that proceeds with reference to the accompanying drawings.

### BRIEF DESCRIPTION OF THE DRAWINGS

The illustrative embodiments will be better understood after reading the following detailed description with reference to the appended drawings, in which:

FIG. 1 depicts an exemplary prior art deadlock detection system;

FIG. 2 depicts an exemplary deadlock detection system in accordance with the present invention;

FIG. 3 depicts an exemplary deadlock detection method in accordance with the present invention;

FIG. 4 depicts an exemplary list of connection identifiers in accordance with the present invention;

FIG. 5 depicts exemplary connection information in accordance with the present invention;

FIG. 6 a block diagram representing an exemplary network environment having a variety of computing devices in which the present invention may be implemented; and

FIG. 7 is a block diagram of an exemplary representing an exemplary computing device in which the present invention may be implemented.

### DETAILED DESCRIPTION OF ILLUSTRATIVE EMBODIMENTS

The subject matter of the present invention is described with specificity to meet statutory requirements. However, the description itself is not intended to limit the scope of this patent. Rather, the inventors have contemplated that the claimed subject matter might also be embodied in other ways, to include different acts or elements similar to the ones described in this document, in conjunction with other present or future technologies.

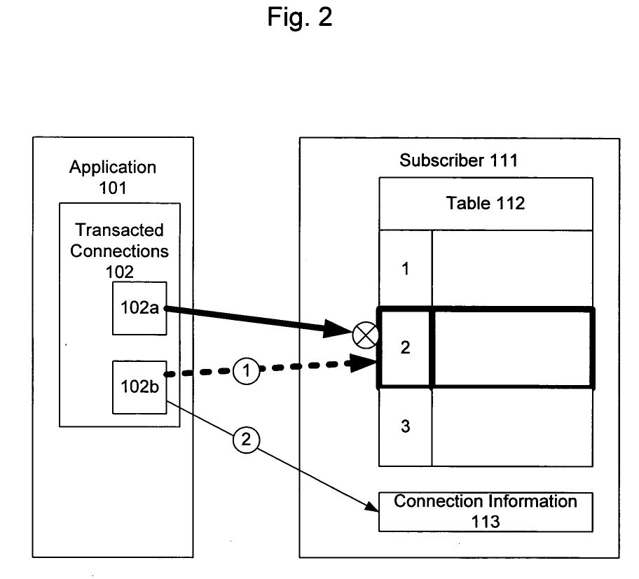

An exemplary deadlock detection system in accordance with the present invention is shown in FIG. 2. Application 101 manages transacted connections 102, including Connections A and B. Application 101 may be, for example, a distribution agent or another client application. Transacted connections 102 replicate data from application 101 to data table 112 within subscriber 111. Subscriber 111 may be, for example, a database server or another back end data store.

As should be appreciated, while Connections A and B are attempting to access rows of data table 112, the present invention is not limited to connections which access rows and tables. The present invention may be used with connections to any resource within a subscriber, including, but not limited to, one or more rows, columns, tables, objects, files, and the like. Additionally, while only two transacted connections 102 are depicted, the present invention may be implemented with any number of transacted connections. Furthermore, while only a single application 101 is shown, the transacted connections 102 may be distributed among more than one application on more than one computing device.

As set forth above, a deadlock has occurred between Connections A and B. Specifically, because Connection B has already acquired a lock on row 2, Connection A is blocked from accessing row 2, as represented by the encircled “X” blocking the connection. The transaction cannot be committed until both Connections A and B are ready to commit. However, Connection B cannot release its lock on row 2 until the transaction has committed.

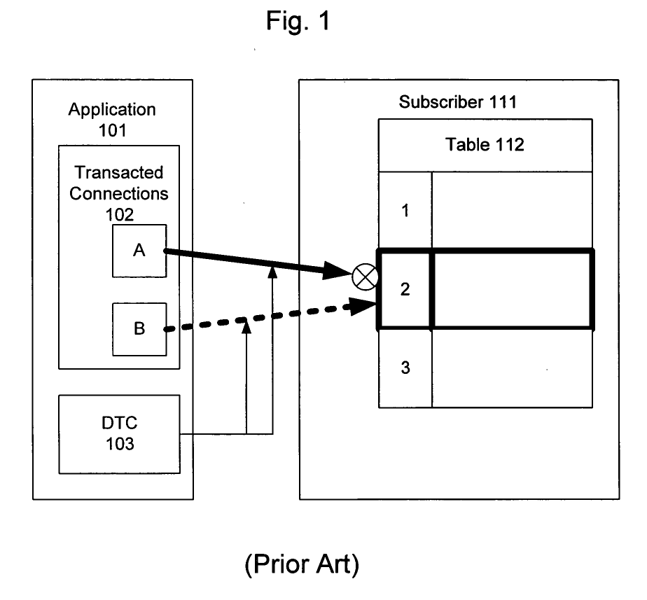

Unlike the prior art system of FIG. 1, the system of FIG. 2 does not include a distributed transaction coordinator (DTC) 103 to monitor Connections A and B and detect the deadlock. However, rather than employing an additional separate DTC connection 103, the system of FIG. 2 takes advantage of existing idle Connection B. Specifically, once Connection B becomes ready to commit and reaches its idle state, it is used to query subscriber 111 and obtain connection information 113, which is used to detect deadlocks as will be described in detail below.

FIG. 2 depicts the dual use of Connection B in accordance with the present invention. Specifically, FIG. 2 depicts stage “1”, at which the connection reaches its idle state. Additionally, FIG. 2 depicts subsequent stage “2”, at which the connection is used to query data store 111 for connection information 113. By using an existing transacted connection 102 rather than separate DTC monitoring connection 103, the present invention conserves network bandwidth and system processing capability.

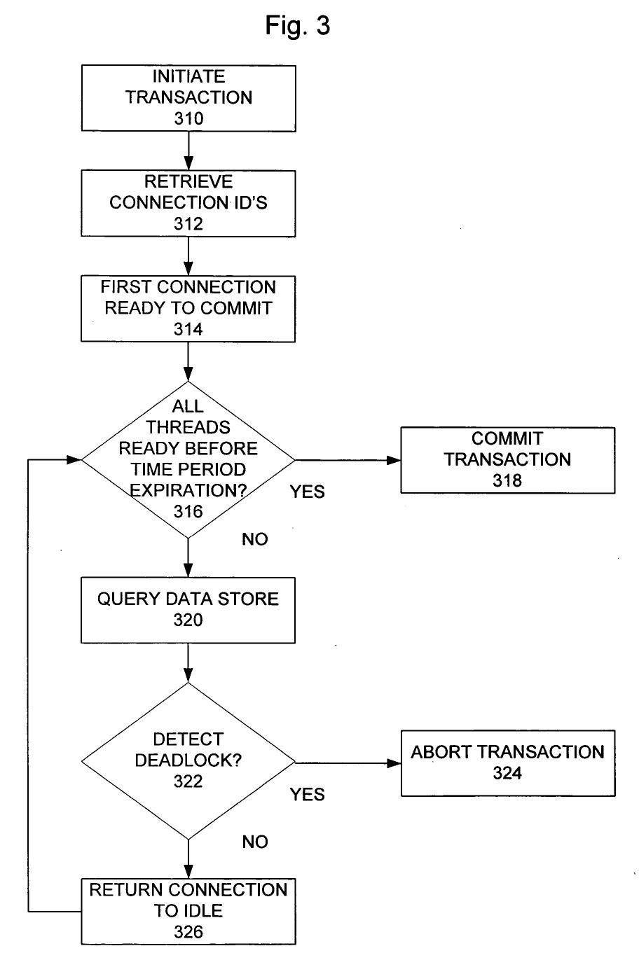

An exemplary deadlock detection method in accordance with the present invention is depicted in FIG. 3. At act 310, a distributed transaction is initiated. The transaction replicates data from application 101 and possibly other applications to subscriber 111. The transaction involves a plurality of transacted connections 102.

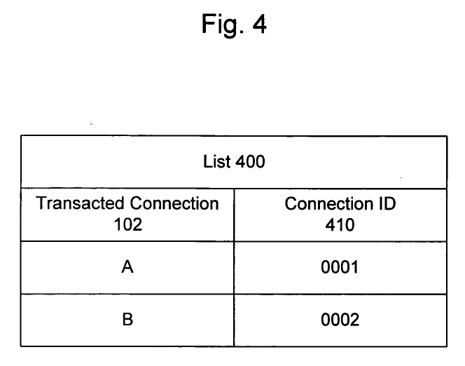

At optional act 312, application 101 queries subscriber 111 to retrieve a list of connection identifiers from subscriber 111. The connection identifiers are used to identify the transacted connections 102 at subscriber 111, as will be described in detail below with reference to act 320. If subscriber 111 is a database server, then the connection identifiers may be, for example, server process identifiers (SPID's). An exemplary list of connection identifiers in accordance with the present invention is depicted in FIG. 4. List 400 has a transacted connection column 102, including transacted connections A and B. List 400 also has a connection identifier column 410, including corresponding connection identifiers for the listed transacted connections 102. A connection identifier list such as list 400 may be stored at application 101.

At act 314, a first transacted connection 102 reaches the ready to commit state. For example, at act 314, Connection B will reach the ready to commit state, acquire a lock on row 2, and become an idle connection. Act 314 is represented by stage “1” in FIG. 2. When, the first transacted connection 102 becomes ready to commit, application 101 begins counting of a pre-determined time period.

At act 316, it is determined whether, prior to the expiration of the pre-determined time period, all of the transacted connections 102 have reached the ready to commit state. If so, then, at act 318, the transaction is committed. If not, then it is possible that a deadlock has occurred, and subscriber 111 is queried to make this determination.

The pre-determined time period is preferably long enough so that subscriber 111 is not overburdened with queries form application 101, thereby slowing the performance of subscriber 111. The pre-determined time period is also preferably short enough so that transacted connections 102 do not remain blocked for extended periods of time, thereby slowing the transaction processing time. The pre-determined time period is preferably 30 seconds, however, other time periods may be used in accordance with the present invention. The time period may be a set period or may vary based on, for example, a number of connections attempting to access the subscriber 111 and a desired transaction performance time. The time period may be set automatically by application 101 and/or subscriber 111 or may be manually selected by a user.

At act 320, application 101 queries subscriber 111 with an idle transacted connection 102 to obtain connection information 113. The connection information 113 is maintained by subscriber 111 and may include a list of all connections to subscriber 111 and their corresponding connection status. The connection status may include an indication of whether a corresponding connection is blocked and, if so, the identity of the blocking connection. Each connection may be identified within connection information 113 according to its corresponding connection identifier.

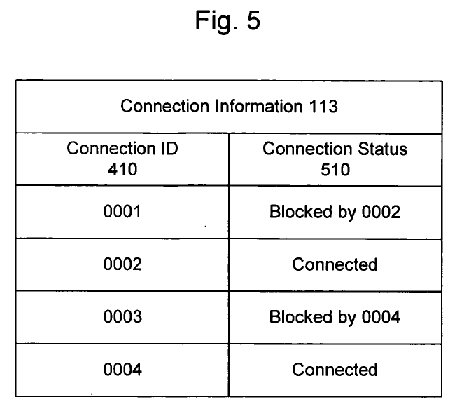

The connection information 113 may be stored at subscriber 113 in a connection information table. Referring now to FIG. 5, exemplary connection information table 500 includes a connection identifier column 410, which includes a connection identifiers for each connection to subscriber 111. Connection identifier table 500 also includes a connection status column 510, which includes a corresponding connection status for each connection. Connection status column 510 indicates that Connection “0001” (which represents Connection A) is blocked by Connection “0002” (which represents Connection B). Connection status column 510 also indicates that Connection “0002” is connected. Table 500 also includes connection information 113 for connections 0003 and 0004, which are connections to subscriber 111 form other transactions.

Importantly, if, at act 312, application 101 has already retrieved a list of connection identifiers for each of the transacted connections 102, then application 101 is able to query and retrieve only the connection information 113 for the transacted connections 102. Thus, application 101 may request only connection information 113 for connections 0001 and 0002. Application 101 need not request connection information 113 for connections 0003 and 0004, thereby reducing the flow of data and speeding the transaction processing time.

At act 322, application 101 determines, based on the retrieved connection information 113, whether a deadlock has occurred. Importantly, to make this determination, application 101 examines connection information 113 to determine whether any of the transacted connections 102 have a corresponding blocking connection that is part of the same transaction. If one of the blocking connections are within the same transaction, the a deadlock has occurred. For example, because Connection B, which is blocking Connection A, is in the same transaction as Connection A, a deadlock has occurred.

If, at act 322, a deadlock is detected, then, at act 324 the transaction is aborted. If there is a conflict between transacted connections, then the conflict may be resolved using well known conflict resolution techniques. Once the conflict is resolved, the transaction may be retried.

If, at act 322, no deadlock is detected, then, at act 326, the querying connection is returned to its idle state. Although a deadlock is present between exemplary Connection A and B of FIG. 2, there are several circumstances in which a deadlock may not be present. For example, a connection may be blocked by a connection from another transaction. In this scenario, it is simply necessary to wait until the other connection either commits or aborts, and the locks are relinquished. Additionally, a deadlock may not be present if one of the transacted connections 102 is changing large amounts of complex data, requiring an extended processing time. Furthermore, a deadlock may not be present if an error has prevented a transacted connection 102 from properly accessing a resource. For example, a transacted connection 102 may attempt to change a adapt table that does not exist.

If a deadlock is not detected, then application 101 may begin to recount the pre-determined time period, and subscriber 111 may be recursively requeried until either the transaction commits or a deadlock is detected. Subscriber 111 is recursively requeried because, even if a deadlock is not present at the first query, a deadlock may occur at some point in the future, particularly as blocking connections from other transactions relinquish their locks on subscriber resources.

As is apparent from the above, all or portions of the various systems, methods, and aspects of the present invention may be embodied in hardware, software, or a combination of both. When embodied in software, the methods and apparatus of the present invention, or certain aspects or portions thereof, may be embodied in the form of program code (i.e., instructions). This program code may be stored on a computer-readable medium, such as a magnetic, electrical, or optical storage medium, including without limitation a floppy diskette, CD-ROM, CD-RW, DVD-ROM, DVD-RAM, magnetic tape, flash memory, hard disk drive, or any other machine-readable storage medium, wherein, when the program code is loaded into and executed by a machine, such as a computer or server, the machine becomes an apparatus for practicing the invention. A computer on which the program code executes will generally include a processor, a storage medium readable by the processor (including volatile and non-volatile memory and/or storage elements), at least one input device, and at least one output device. The program code may be implemented in a high level procedural or object oriented programming language. Alternatively, the program code can be implemented in an assembly or machine language. In any case, the language may be a compiled or interpreted language.

The present invention may also be embodied in the form of program code that is transmitted over some transmission medium, such as over electrical wiring or cabling, through fiber optics, over a network, including a local area network, a wide area network, the Internet or an intranet, or via any other form of transmission, wherein, when the program code is received and loaded into and executed by a machine, such as a computer, the machine becomes an apparatus for practicing the invention.

When implemented on a general-purpose processor, the program code may combine with the processor to provide a unique apparatus that operates analogously to specific logic circuits.

Moreover, the invention can be implemented in connection with any computer or other client or server device, which can be deployed as part of a computer network, or in a distributed computing environment. In this regard, the present invention pertains to any computer system or environment having any number of memory or storage units, and any number of applications and processes occurring across any number of storage units or volumes, which may be used in connection with processes for persisting objects in a database store in accordance with the present invention. The present invention may apply to an environment with server computers and client computers deployed in a network environment or distributed computing environment, having remote or local storage. The present invention may also be applied to standalone computing devices, having programming language functionality, interpretation and execution capabilities for generating, receiving and transmitting information in connection with remote or local services.

Distributed computing facilitates sharing of computer resources and services by exchange between computing devices and systems. These resources and services include, but are not limited to, the exchange of information, cache storage, and disk storage for files. Distributed computing takes advantage of network connectivity, allowing clients to leverage their collective power to benefit the entire enterprise. In this regard, a variety of devices may have applications, objects or resources that may implicate processing performed in connection with the object persistence methods of the present invention.

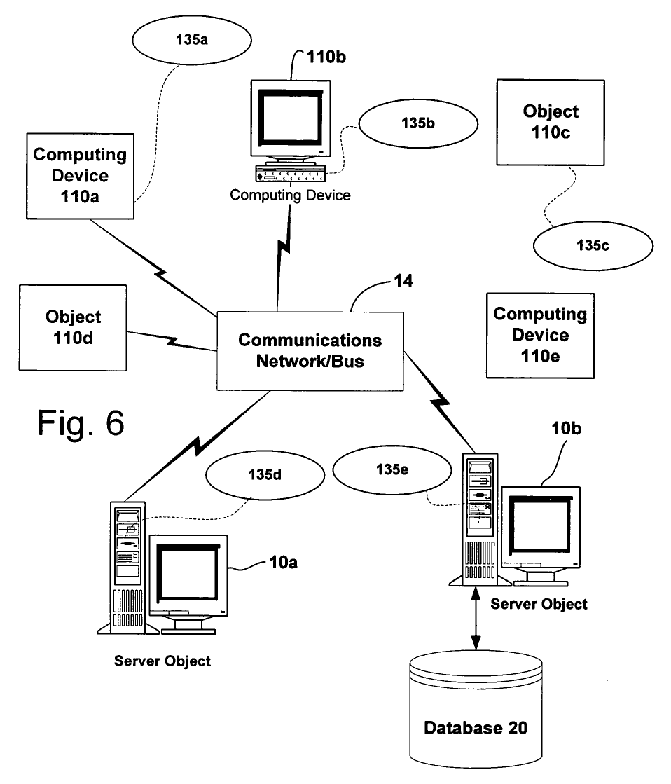

FIG. 6 provides a schematic diagram of an exemplary networked or distributed computing environment. The distributed computing environment comprises computing objects 10a, 10b, etc. and computing objects or devices 110a, 110b, 110c, etc. These objects may comprise programs, methods, subscribers, programmable logic, etc. The objects may comprise portions of the same or different devices such as PDAs, televisions, MP3 players, personal computers, etc. Each object can communicate with another object by way of the communications network 14. This network may itself comprise other computing objects and computing devices that provide services to the system of FIG. 6, and may itself represent multiple interconnected networks. In accordance with an aspect of the invention, each object 10a, 10b, etc. or 110a, 110b, 110c, etc. may contain an application that might make use of an API, or other object, software, firmware and/or hardware, to request use of the processes used to implement the object persistence methods of the present invention.

It can also be appreciated that an object, such as 110c, may be hosted on another computing device 10a, 10b, etc. or 110a, 110b, etc. Thus, although the physical environment depicted may show the connected devices as computers, such illustration is merely exemplary and the physical environment may alternatively be depicted or described comprising various digital devices such as PDAs, televisions, MP3 players, etc., software objects such as interfaces, COM objects and the like.

There are a variety of systems, components, and network configurations that support distributed computing environments. For example, computing systems may be connected together by wired or wireless systems, by local networks or widely distributed networks. Currently, many of the networks are coupled to the Internet, which provides the infrastructure for widely distributed computing and encompasses many different networks. Any of the infrastructures may be used for exemplary communications made incident to the present invention.

The Internet commonly refers to the collection of networks and gateways that utilize the TCP/IP suite of protocols, which are well-known in the art of computer networking. TCP/IP is an acronym for “Transmission Control Protocol/Internet Protocol.” The Internet can be described as a system of geographically distributed remote computer networks interconnected by computers executing networking protocols that allow users to interact and share information over the network(s). Because of such wide-spread information sharing, remote networks such as the Internet have thus far generally evolved into an open system for which developers can design software applications for performing specialized operations or services, essentially without restriction.

Thus, the network infrastructure enables a host of network topologies such as client/server, peer-to-peer, or hybrid architectures. The “client” is a member of a class or group that uses the services of another class or group to which it is not related. Thus, in computing, a client is a process, i.e., roughly a set of instructions or tasks, that requests a service provided by another program. The client process utilizes the requested service without having to “know” any working details about the other program or the service itself. In a client/server architecture, particularly a networked system, a client is usually a computer that accesses shared network resources provided by another computer, e.g., a server. In the example of FIG. 6, computers 110a, 110b, etc. can be thought of as clients and computer 10a, 10b, etc. can be thought of as servers, although any computer could be considered a client, a server, or both, depending on the circumstances. Any of these computing devices may be processing data in a manner that implicates the object persistence techniques of the invention.

A server is typically a remote computer system accessible over a remote or local network, such as the Internet. The client process may be active in a first computer system, and the server process may be active in a second computer system, communicating with one another over a communications medium, thus providing distributed functionality and allowing multiple clients to take advantage of the information-gathering capabilities of the server. Any software objects utilized pursuant to the persistence mechanism of the invention may be distributed across multiple computing devices.

Client(s) and server(s) may communicate with one another utilizing the functionality provided by a protocol layer. For example, Hypertext Transfer Protocol (HTTP) is a common protocol that is used in conjunction with the World Wide Web (WWW), or “the Web.” Typically, a computer network address such as an Internet Protocol (IP) address or other reference such as a Universal Resource Locator (URL) can be used to identify the server or client computers to each other. The network address can be referred to as a URL address. Communication can be provided over any available communications medium.

Thus, FIG. 6 illustrates an exemplary networked or distributed environment, with a server in communication with client computers via a network/bus, in which the present invention may be employed. The network/bus 14 may be a LAN, WAN, intranet, the Internet, or some other network medium, with a number of client or remote computing devices 110a, 110b, 110c, 110d, 110e, etc., such as a portable computer, handheld computer, thin client, networked appliance, or other device, such as a VCR, TV, oven, light, heater and the like in accordance with the present invention. It is thus contemplated that the present invention may apply to any computing device in connection with which it is desirable to maintain a persisted object.

In a network environment in which the communications network/bus 14 is the Internet, for example, the servers 10a, 10b, etc. can be servers with which the clients 110a, 110b, 110c, 110d, 110e, etc. communicate via any of a number of known protocols such as HTTP. Servers 10a, 10b, etc. may also serve as clients 110a, 110b, 110c, 110d, 110e, etc., as may be characteristic of a distributed computing environment.

Communications may be wired or wireless, where appropriate. Client devices 110a, 110b, 110c, 110d, 110e, etc. may or may not communicate via communications network/bus 14, and may have independent communications associated therewith. For example, in the case of a TV or VCR, there may or may not be a networked aspect to the control thereof. Each client computer 110a, 110b, 110c, 110d, 110e, etc. and server computer 10a, 10b, etc. may be equipped with various application program modules or objects 135 and with connections or access to various types of storage elements or objects, across which files or data streams may be stored or to which portion(s) of files or data streams may be downloaded, transmitted or migrated. Any computer 10a, 10b, 110a, 110b, etc. may be responsible for the maintenance and updating of a database, memory, or other storage element 20 for storing data processed according to the invention. Thus, the present invention can be utilized in a computer network environment having client computers 110a, 110b, etc. that can access and interact with a computer network/bus 14 and server computers 10a, 10b, etc. that may interact with client computers 110a, 110b, etc. and other like devices, and databases 20.

FIG. 6 and the following discussion are intended to provide a brief general description of a suitable computing device in connection with which the invention may be implemented. For example, any of the client and server computers or devices illustrated in FIG. 6 may take this form. It should be understood, however, that handheld, portable and other computing devices and computing objects of all kinds are contemplated for use in connection with the present invention, i.e., anywhere from which data may be generated, processed, received and/or transmitted in a computing environment. While a general purpose computer is described below, this is but one example, and the present invention may be implemented with a thin client having network/bus interoperability and interaction. Thus, the present invention may be implemented in an environment of networked hosted services in which very little or minimal client resources are implicated, e.g., a networked environment in which the client device serves merely as an interface to the network/bus, such as an object placed in an appliance. In essence, anywhere that data may be stored or from which data may be retrieved or transmitted to another computer is a desirable, or suitable, environment for operation of the object persistence methods of the invention.

Although not required, the invention can be implemented via an operating system, for use by a developer of services for a device or object, and/or included within application or server software that operates in accordance with the invention. Software may be described in the general context of computer-executable instructions, such as program modules, being executed by one or more computers, such as client workstations, servers or other devices. Generally, program modules include routines, programs, objects, components, data structures and the like that perform particular tasks or implement particular abstract data types. Typically, the functionality of the program modules may be combined or distributed as desired in various embodiments. Moreover, the invention may be practiced with other computer system configurations and protocols. Other well known computing systems, environments, and/or configurations that may be suitable for use with the invention include, but are not limited to, personal computers (PCs), automated teller machines, server computers, hand-held or laptop devices, multi-processor systems, microprocessor-based systems, programmable consumer electronics, network PCs, appliances, lights, environmental control elements, minicomputers, mainframe computers and the like.

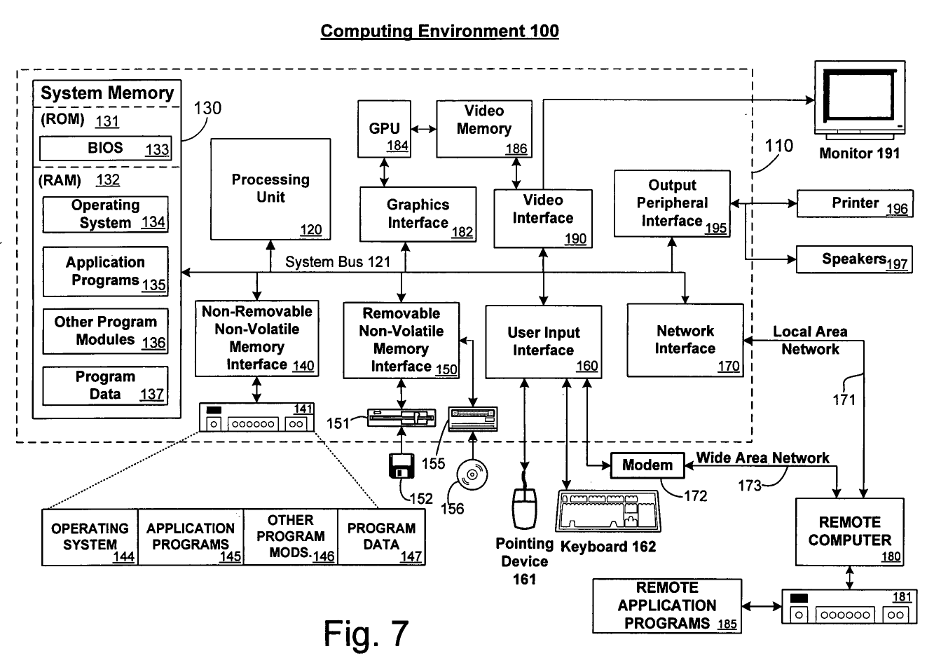

FIG. 7 thus illustrates an example of a suitable computing system environment 100 in which the invention may be implemented, although as made clear above, the computing system environment 100 is only one example of a suitable computing environment and is not intended to suggest any limitation as to the scope of use or functionality of the invention. Neither should the computing environment 100 be interpreted as having any dependency or requirement relating to any one or combination of components illustrated in the exemplary operating environment 100.

With reference to FIG. 7, an exemplary system for implementing the invention includes a general purpose computing device in the form of a computer 110. Components of computer 110 may include, but are not limited to, a processing unit 120, a system memory 130, and a system bus 121 that couples various system components including the system memory to the processing unit 120. The system bus 121 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus (also known as Mezzanine bus).

Computer 110 typically includes a variety of computer readable media. Computer readable media can be any available media that can be accessed by computer 110 and includes both volatile and nonvolatile media, removable and non-removable media. By way of example, and not limitation, computer readable media may comprise computer storage media and communication media. Computer storage media include both volatile and nonvolatile, removable and non-removable media implemented in any method or technology for storage of information such as computer readable instructions, data structures, program modules or other data. Computer storage media include, but are not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other medium which can be used to store the desired information and which can be accessed by computer 110. Communication media typically embody computer readable instructions, data structures, program modules or other data in a modulated data signal such as a carrier wave or other transport mechanism and include any information delivery media. The term “modulated data signal” means a signal that has one or more of its characteristics set or changed in such a manner as to encode information in the signal. By way of example, and not limitation, communication media include wired media such as a wired network or direct-wired connection, and wireless media such as acoustic, RF, infrared and other wireless media. Combinations of any of the above should also be included within the scope of computer readable media.

The system memory 130 includes computer storage media in the form of volatile and/or nonvolatile memory such as read only memory (ROM) 131 and random access memory (RAM) 132. A basic input/output system 133 (BIOS), containing the basic routines that help to transfer information between elements within computer 110, such as during start-up, is typically stored in ROM 131. RAM 132 typically contains data and/or program modules that are immediately accessible to and/or presently being operated on by processing unit 120. By way of example, and not limitation, FIG. 7 illustrates operating system 134, application programs 135, other program modules 136, and program data 137.

The computer 110 may also include other removable/non-removable, volatile/nonvolatile computer storage media. By way of example only, FIG. 6 illustrates a hard disk drive 141 that reads from or writes to non-removable, nonvolatile magnetic media, a magnetic disk drive 151 that reads from or writes to a removable, nonvolatile magnetic disk 152, and an optical disk drive 155 that reads from or writes to a removable, nonvolatile optical disk 156, such as a CD-RW, DVD-RW or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM and the like. The hard disk drive 141 is typically connected to the system bus 121 through a non-removable memory interface such as interface 140, and magnetic disk drive 151 and optical disk drive 155 are typically connected to the system bus 121 by a removable memory interface, such as interface 150.

The drives and their associated computer storage media discussed above and illustrated in FIG. 7 provide storage of computer readable instructions, data structures, program modules and other data for the computer 110. In FIG. 7 , for example, hard disk drive 141 is illustrated as storing operating system 144, application programs 145, other program modules 146 and program data 147. Note that these components can either be the same as or different from operating system 134, application programs 135, other program modules 136 and program data 137. Operating system 144, application programs 145, other program modules 146 and program data 147 are given different numbers here to illustrate that, at a minimum, they are different copies. A user may enter commands and information into the computer 110 through input devices such as a keyboard 162 and pointing device 161, such as a mouse, trackball or touch pad. Other input devices (not shown) may include a microphone, joystick, game pad, satellite dish, scanner, or the like. These and other input devices are often connected to the processing unit 120 through a user input interface 160 that is coupled to the system bus 121, but may be connected by other interface and bus structures, such as a parallel port, game port or a universal serial bus (USB). A graphics interface 182 may also be connected to the system bus 121. One or more graphics processing units (GPUs) 184 may communicate with graphics interface 182. A monitor 191 or other type of display device is also connected to the system bus 121 via an interface, such as a video interface 190, which may in turn communicate with video memory 186. In addition to monitor 191, computers may also include other peripheral output devices such as speakers 197 and printer 196, which may be connected through an output peripheral interface 195.

The computer 110 may operate in a networked or distributed environment using logical connections to one or more remote computers, such as a remote computer 180. The remote computer 180 may be a personal computer, a server, a router, a network PC, a peer device or other common network node, and typically includes many or all of the elements described above relative to the computer 110, although only a memory storage device 181 has been illustrated in FIG. 7 . The logical connections depicted in FIG. 7 include a local area network (LAN) 171 and a wide area network (WAN) 173, but may also include other networks/buses. Such networking environments are commonplace in homes, offices, enterprise-wide computer networks, intranets and the Internet.

When used in a LAN networking environment, the computer 110 is connected to the LAN 171 through a network interface or adapter 170. When used in a WAN networking environment, the computer 110 typically includes a modem 172 or other means for establishing communications over the WAN 173, such as the Internet. The modem 172, which may be internal or external, may be connected to the system bus 121 via the user input interface 160, or other appropriate mechanism. In a networked environment, program modules depicted relative to the computer 110, or portions thereof, may be stored in the remote memory storage device. By way of example, and not limitation, FIG. 7 illustrates remote application programs 185 as residing on memory device 181. It will be appreciated that the network connections shown are exemplary and other means of establishing a communications link between the computers may be used.

While the present invention has been described in connection with the preferred embodiments of the various figures, it is to be understood that other similar embodiments may be used or modifications and additions may be made to the described embodiment for performing the same function of the present invention without deviating therefrom. Therefore, the present invention should not be limited to any single embodiment, but rather should be construed in breadth and scope in accordance with the appended claims.

1. A method for detecting a deadlock among a plurality of connections within a transaction that replicate data to a subscriber, the method comprising:
querying the subscriber using an idle connection within the transaction to identify a blocking connection that is blocking another connection within the transaction; and
determining whether the blocking connection is also within the transaction.

2. The method of claim 1, comprising querying the subscriber with the idle connection that is ready to commit.

3. The method of claim 2, comprising querying the subscriber after the connection has been ready to commit for a predetermined time period.

4. The method of claim 3, comprising querying the subscriber after the connection has been ready to commit for a predetermined time period that is determined based on a number of connections to the subscriber.

5. The method of claim 1, further comprising aborting the transaction if the blocking connection is also within the transaction.

6. The method of claim 1, further comprising, if the blocking connection is not within the transaction, then:
returning the idle connection to its idle state; and
recursively querying the subscriber until the transaction commits or aborts.

7. The method of claim 1, further comprising retrieving from the subscriber a list of connection identifiers for the connections within the transaction, the connection identifiers being used to identify the connections within the transaction when querying the subscriber.

8. A method for monitoring a plurality of connections within a transaction that replicate data to a subscriber, the method comprising:
initiating counting of a pre-determined time period when a connection within the transaction becomes ready to commit;
determining whether, prior to expiration of the pre-determined time period, all of the other connections within the transaction are also ready to commit;
if so, then committing the transaction;
if not, then determining whether a deadlock has occurred between connections within the transaction.

9. The method of claim 8, comprising initiating counting of a pre-determined time period that is determined based on a number of connections to the subscriber.

10. The method of claim 8, wherein determining whether a deadlock has occurred between connections within the transaction comprises:
querying the subscriber using an idle connection within the transaction to identify a blocking connection that is blocking another connection within the transaction;
determining whether the blocking connection is also within the transaction; and
if so, then determining that a deadlock has occurred; and
if not, then determining that a deadlock has not occurred.

11. The method of claim 10, further comprising retrieving from the subscriber a list of connection identifiers for the connections within the transaction, the connection identifiers being used to identify the connections within the transaction when querying the subscriber.

12. The method of claim 8, further comprising aborting the transaction if a deadlock has occurred.

13. The method of claim 8, further comprising, if a deadlock has not occurred, then returning to the step of initiating counting of a pre-determined time period.

14. A system for detecting a deadlock among a plurality of connections within a transaction that replicate data to a subscriber, the system comprising:
the subscriber; and
an application that queries the subscriber with an idle connection within the transaction to determine whether another connection within the transaction is blocked by a blocking connection that is also within the transaction.

15. The system of claim 14, wherein the subscriber maintains a table that, for each blocked connection to the subscriber, identifies a corresponding blocking connection.

16. The method of claim 15, wherein the table identifies each connection by a connection identifier.

17. The method of claim 16, wherein the application retrieves a list of the connection identifiers for each connection within the transaction.

18. The system of claim 14, wherein the idle connection is ready to commit.

19. The system of claim 18, wherein the idle connection has been ready to commit for a predetermined time period prior to querying the subscriber.

20. The system of claim 14, wherein the application aborts the transaction if the blocking connection is also within the transaction.

21. The system of claim 14, wherein the idle connection recursively requeries the subscriber until the transaction commits or aborts.

22. The system of claim 14, wherein the subscriber is a database server.

23. A computer-readable medium having stored thereon computer executable instructions for performing the following steps:
querying a subscriber with an idle connection within a transaction to identify a blocking connection that is blocking another connection within the transaction; and
determining whether the blocking connection is also within the transaction.

24. The computer-readable medium of claim 23, wherein the idle connection is ready to commit.

25. The computer-readable medium of claim 24, wherein the idle connection has been ready to commit for a predetermined time period prior to querying the subscriber.

26. The computer-readable medium of claim 23, wherein the computer executable instructions are further for performing the step of aborting the transaction if the blocking connection is also within the transaction.

27. The computer-readable medium of claim 23, wherein the computer executable instructions are further for performing the step of recursively requerying the subscriber until the transaction commits or aborts.

28. The computer-readable medium of claim 23, wherein the computer executable instructions are further for performing the step of retrieving from the subscriber a list of connection identifiers for the connections within the transaction, the connection identifiers being used to identify the connections within the transaction when querying the subscriber.
